(19) United States
(12) Patent Application Publication
(10) Pub. No.: US 2013/0333739 A1
(43) Pub. Date: Dec. 19, 2013

(54) PHOTOVOLTAIC MODULES

(71) Applicants: Jingsong Huang, London (GB); Jonathan Halls, Cambridge (GB)

(72) Inventors: Jingsong Huang, London (GB); Jonathan Halls, Cambridge (GB)

(73) Assignee: The Solar Press UK Ltd, London (UK)

(21) Appl. No.: 13/699,896

(22) PCT Filed: May 25, 2011
(86) PCT No.: PCT/GB11/50988

§ 371 Date: May 3, 2013

(30) Foreign Application Priority Data
May 25, 2010 (GB) 1008697.3

(51) Int. Cl. H01L 31/05

(52) U.S. Cl. CPC H01L 31/0504
USPC 136/244

(57) ABSTRACT

A photovoltaic module comprises at least a first and a second photovoltaic cell, the two cells being adjacent and connected, e.g. in series, and wherein, in use, current flow through a photoactive layer of the first photovoltaic cell is in a different, e.g. substantially opposite, direction, relative to the substrate, to that through a photoactive layer of the second photovoltaic cell.

The present invention relates to photovoltaic modules and methods of their manufacture and is especially, but not exclusively, related to devices and apparatus comprising such modules.

A photovoltaic solar module converts light (including sunlight and artificial light) into electrical energy that may be used to power an electrical product or charge a battery. A solar module comprises photovoltaic cells, which contain a photoactive material that absorbs electromagnetic radiation and converts it into electrical energy via the photovoltaic effect.

In a solar module, photovoltaic cells are connected in series and/or parallel electrical configurations to deliver the required current and voltage output to drive a particular electrical load, such as a battery to be charged.

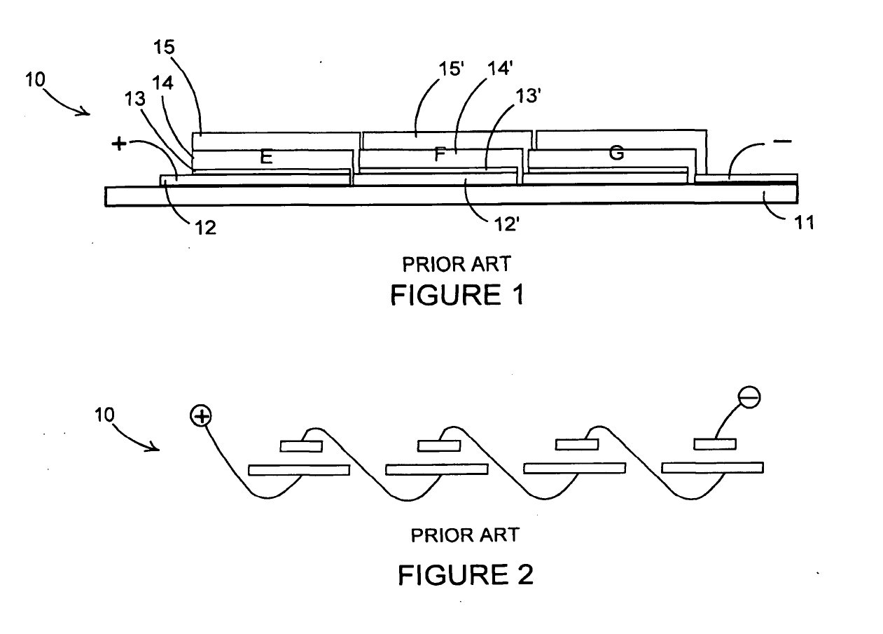

With reference to FIGS. 1 to 3, the architecture of a conventional photovoltaic module 10 comprising an array of standard structure photovoltaic cells is shown. The module 10 comprises, in series, first E, second F and third G photovoltaic cells, each of which having being deposited onto a common transparent glass or plastic substrate 11.

The cells E, F, G each have an identical configuration therefore only one cell, the first cell E, will be described in detail.

The first cell E comprises, from the substrate 11, a first electrode layer 12, e.g. of indium tin oxide (ITO), an interface layer 13, e.g. a hole collection layer such as PEDOT:PSS, a photoactive layer 14, e.g. P3HT:PCBM and a second electrode layer 15 e.g. of aluminium. The cell E may comprise a further interface layer (not shown), e.g. an electron collection layer, disposed between the photoactive layer 14 and the second electrode layer 15.

Further optional layers may be provided in the device, e.g. one or more electron transport layers between the photoactive layer 14 and one or other of the first 12 and second 15 electrode layers and/or a hole transport layer between the other of the first 12 and second 15 electrode layers.

The photoactive layer 14 absorbs photons from light incident on the cell and generates electrical charges.

The hole collection layer facilitates extraction of holes from the photoactive layer 14 and conveys them to the electrode contact. Further, the hole collection layer may serve to block electrons, thereby providing electrode selectivity.

The electron collection layer facilitates extraction of electrons from the photoactive layer 14 and conveys them to the electrode contact. Further, the electron collection layer may serve to block holes, thereby providing electrode selectivity.

It will be appreciated that each layer is patterned to form a discrete unit cell.

A cell E is typically formed by depositing, e.g. by printing or sputtering followed by a subtractive patterning process the first electrode layer 12 onto the substrate 11. The hole collection layer 13 is subsequently deposited over the first electrode layer 12 before the photoactive layer 14, e.g. an organic photoactive layer, is deposited thereon. Finally, to complete the cell E, the second electrode layer 15 is deposited over the photoactive layer 14.

The photoactive layer 14 and second electrode layer 15 are deposited such that the layers 14, 15 make a connection with the first electrode layer 12′ of the adjacent cell F. As will be appreciated, this architecture provides a module 10 whereby each layer of a cell is discrete from the corresponding layer of an adjacent cell. For example, the first electrode layer 12 of cell E is not in contact with the first electrode layer 12′ of cell F and so on. This is necessary in order for the current to flow from one cell to another, i.e. so that the cells that form module 10 are connected in series and the voltage output of the module is the sum of the voltages of the individual cells.

Moreover, it is important to avoid an electrical contact between electrode layers of the same cell since this leads to electrical shorting.

Other methods of ensuring that the cells are in series have been proposed. One such method involves utilizing a separate metallization step following the deposition of the final electrode layer. Again, in such modules, each layer is patterned and discrete from its corresponding layer in an adjacent cell. However, because each layer is patterned, complicated multilayer patterning techniques and highly accurate tools are required in order to accurately assemble such an architecture.

Moreover, in order to ensure that such cells function properly the gaps between adjacent cells need to be relatively large. This ensures effective overlap between the upper electrode of one cell with the lower electrode of the adjacent cell, and thus electrical continuity with low contact resistance and high manufacturing yield.

Additionally, it is necessary to prevent shorting between the two electrodes in the same cell, which requires the active layer to extend beyond the edge of the lower electrode where the upper electrode crosses over the lower electrode or any conducting interlayer, such as PEDOT:PSS.

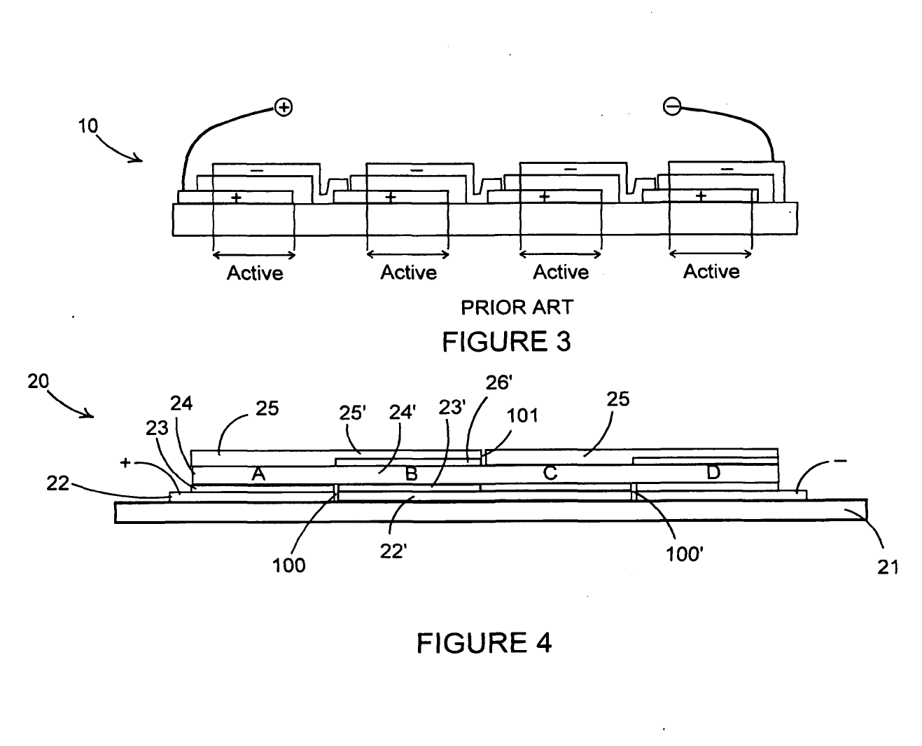

This results in the module having relatively large areas of non-photo activity, as shown in FIG. 3.

The ratio of the photoactive to total (photoactive+non-photo-active) area of a photovoltaic module is known as the aperture ratio.

The aperture ratio of the known modules described above is often well below 50% (see “Going organic: Plextronics gets the first organic photovoltaic (OPV) test modules under sun at NREL”, PV-tech.org, 20 Aug. 2009).

Organic photovoltaic (OPV) cells and modules promise significant advantages in terms of ease and cost of manufacture. One notable advantage is that OPV cells and modules can be manufactured, using deposition techniques such as gravure or screen printing, as thin film layers which may be lightweight and/or flexible, thereby easing installation and offering increased versatility. Unlike crystalline silicon solar cells which must be connected together using external links to form a module, OPV modules may be formed monolithically, with the cell interconnections formed during the fabrication of the cells themselves.

However, once significant drawback is that OPV modules in a series-configuration require for there to be a connection between the first electrode layer of one cell and the second electrode layer of opposite polarity of an adjacent cell, as shown in FIG. 2. Because each cell is identical, the connection must extend through each and every layer of the cell, resulting in the module having significant regions of non-photo activity.

Further, it has been discovered that OPV modules often exhibit a reduction in module efficiency or even total module failure due to electrical shorting of undivided cells, e.g. when the layers are unevenly deposited. In addition, if there is a break in the series connection between the upper electrode of one cell with the lower electrode of a neighboring cell, the whole module will fail as no current can flow through the module.

It is a first non-exclusive object of the invention to provide a photovoltaic module which may have a greater aperture ratio than prior art modules.

It is a second non-exclusive object of the invention to provide a photovoltaic module which may have increased module power conversion efficiency than prior art modules.

A first aspect of the present invention provides a photovoltaic module comprising at least a first and a second photovoltaic cell, the two cells being adjacent and connected, e.g. in series, and wherein, in use, current flow through a photoactive layer of the first photovoltaic cell is in a substantially opposite direction, relative to the substrate, to that through a photoactive layer of the second photovoltaic cell.

A second aspect of the present invention provides a photovoltaic module comprising a photovoltaic cell of standard structure connected in series with a photovoltaic cell of inverted structure, preferably the two cells being provided on the same substrate.

“Inverted” structure photovoltaic cells are constructed with hole collection layers and electron collection layers switched places either side of the photoactive layer relative to “standard” structure photovoltaic cells, for example comprising in succession a substrate, a first electrode layer, a first electron collection layer, a photoactive layer, a first hole collection layer and a second electrode layer. This has the effect of reversing the polarity of the “inverted” structure as compared to the “standard” structure.

Optionally, the or a photoactive layer is shared between the at least two cells.

Optionally, a photoactive layer of at least one cell is discrete.

Preferably, at least one or both photovoltaic cells are organic photovoltaic cells.

A third aspect of the present invention provides a photovoltaic module having two or more photovoltaic cells, each cell comprising a pair of electrodes having an organic photoactive layer interposed therebetween, wherein the photoactive layer is shared between at least two cells.

Preferably, at least one of the two or more cells comprises a hole collection layer and/or an electron collection layer.

The hole collection layer and/or electron collection layer may be interposed between an electrode and the photoactive layer.

Preferably, at least one of the pair of electrodes is at least partially transparent to at least a part of the solar spectrum.

Preferably, the transparent electrode is in contact with a substrate, e.g. a transparent glass or plastic substrate.

This is advantageous if the photoactive layer is to be illuminated through the substrate.

Preferably, the transparent electrode is a transparent conducting oxide (TCO).

Preferably, the TCO comprises a metal oxide, e.g. Indium Tin Oxide (ITO), Fluorine-doped Tin Oxide (FTO) or aluminium doped zinc oxide (AZO), zinc-indium tin oxide (ZITO).

Alternative transparent conductors to TCO may include doped organic polymers, nanotube, nanoparticle or nanowire dispersions, thin metals layers and so on.

The TCO may be deposited by sputtering or other vacuum based processes. Alternatively, sol-gel processing or other such solution based deposition techniques may be used. The TCO may be patterned after deposition, e.g. by a photolithographic or etching techniques, or as part of the deposition process, e.g. by masking or printing.

In some embodiments the substrate and the electrode in contact therewith may be opaque. In such embodiments, the other of the pair of electrodes may be transparent such that light can be transmitted to the photoactive layer, in use.

Preferably, the hole collection layer comprises a conductive polymer such as poly(3,4-ethylenedioxythiophene) poly(styrenesulfonate) (PEDOT:PSS) or other doped polymers e.g. based on polyaniline or polyacetylene, or an inorganic material, such as a metal oxide, e.g. molybdenum oxide (MOₓ), tungsten oxide (WOₓ), vanadium oxide (VO_{X}), nickel oxide NiO, or cuprous oxide Cu₂O.

The hole collection layer may be deposited by solution or vacuum based processes. Preferably, a solution based process is used.

Preferably, the electron collection layer comprises a metal oxide, e.g. titania (TiO₂), zinc oxide, tin oxide, niobium oxide, zirconium oxide and compound oxides (e.g. niobium titanium oxide).

The metal oxide may be deposited using spray pyrolysis. The spray pyrolysis may be performed at any suitable temperature according to the material being deposited and the substrate being used.

Preferably, the pyrolysis temperature may be in the range of 100° C. to 600° C., more preferably in the range of 100° C. to 400° C., and even more preferably in the range of 200° C. to 400° C., e.g. 300° C.

Other techniques for deposition of the electron collecting or other layer or layers may include sol-gel coating, sputtering, ion-assisted vacuum deposition or any other suitable technique.

In some embodiments an or the electron collection layer may comprise an organic compound or composition. For example, the electron collection layer may comprise an optionally doped organic small molecule or polymer.

The hole collection layer and/or electron collection layer may be patterned by additive patterning, e.g. via a masking or printing technique, or by subtractive patterning of a blanket-deposited film, e.g. by photolithography or wet and/or dry etching.

Preferably, the hole collection layer and/or electron collection layer are deposited by solution or vacuum based processes.

Preferably, the hole collection layer is approximately 10 to 100 nm thick, more preferably, 20 to 100 nm thick, even more preferably 30 to 70 nm thick, e.g. 40 to 60 nm thick.

Preferably, the electron collection layer is approximately 5 to 60 nm thick, more preferably 10 to 40 nm thick, even more preferably 10 to 30 nm thick, e.g. 20 nm thick.

Preferably, the photoactive layer is approximately 5 to 1000 nm thick, more preferably 50 to 500 nm thick, even more preferably 100 to 300 nm thick, e.g. 200 nm thick.

In some alternative embodiments, the photoactive layer is approximately 10 to 200 nm thick, e.g. 70 to 100 nm thick.

Preferably, the electrode layer is approximately 20 to 500 nm thick, more preferably 40 to 250 nm thick, even more preferably 60 to 150 nm thick, e.g. 100 nm thick.

Preferably, the photoactive layer is a non-patterned layer. This is advantageous because a processing step is removed, thereby increasing production yield, module efficiency and lowering cost.

Moreover, modules having a single continuous photoactive layer may show greater efficiency, improved performance and a greater aperture ratio.

In addition, the provision of a single continuous photoactive layer may induce a wave guiding effect across the entire module. This may further increase the absorption of photons, thereby increasing the power conversion efficiency of the module.

Preferably, the module comprises a photoactive layer having a common composition. However, in some embodiments of the invention, different active layer compositions may be utilised for different cells within the same photovoltaic module.

Preferably, the photoactive layer comprises a binary system of a donor moiety and an acceptor moiety, mixed together in a single layer. This device architecture is commonly referred to as the Bulk Heterojunction approach. Alternatively the donor and acceptor materials may be applied as a sequence of distinct layers.

Preferably, at least one of the donor moiety or acceptor moiety comprises an organic semiconductor.

Preferably, the acceptor moiety comprises a higher electron affinity and/or ionisation potential than the donor moiety.

This is advantageous because is makes electron transfer to the acceptor moiety energetically favourable.

In some embodiments, both the donor moiety and acceptor moiety comprise organic semiconductors.

In other embodiments, an organic semiconductor donor moiety may be combined with an inorganic semiconductor acceptor moiety.

In other embodiments, an organic semiconductor acceptor moiety may be combined with an inorganic donor moiety.

In other embodiments, additional components to the donor and acceptor materials may be incorporated in the photoactive layer. These may be included to modify the physical, electrical and/or optical properties of the active layer. Examples of additives included to modify the active layer microstructure include 1,8-octaneditiol (as described in Peet, et al., “Efficiency enhancement in low-bandgap polymer solar cells by processing with alkane dithiols,” Nature Mater., 6(7): 497-500, July 2007) and discotic liquid crystals (as described in Appl. Phys. Lett. 96, 183305 (2010) “Improved efficiency of bulk heterojunction poly(3-hexylthiophene):[6,6]-phenyl-C61-butyric acid methyl ester photovoltaic devices using discotic liquid crystal additives” Seonju Jeong, Younghwan Kwon, Byeong-Dae Choi, Harald Ade, and Yoon Soo Han).

Suitable organic donors may include conjugated polymers, such as polyacetylene, co-polymers and derivatives of polythiophenes, e.g. poly(3-hexylthiophene) (P3HT), poly(3-octyl-thiophene) (P3OT), polyfluorenes, silicon-bridged polyfluorenes, polyindenofluorenes, polycarbazoles and poly phenylene vinylenes, for example poly(phenylene-vinylene) (PPV), poly[2-methoxy-5-(2′-ethyl-hexyloxy)-1,4-phenylene vinylene] (MEH-PPV), or small molecule organic semiconductors, such as thiophene based oligomers, phthalocyanines, for example copper- and zinc-phthalocyanine.

Suitable organic acceptors may include conjugated polymers, such as polyacetylene, co-polymers and derivatives of polythiophenes, e.g. poly(3-hexylthiophene) (P3HT), poly(3-octyl-thiophene) (P3OT), polyfluorenes, silicon-bridged polyfluorenes, polyindenofluorenes, polycarbazoles and poly phenylene vinylenes, for example poly(phenylene-vinylene) (PPV), poly[2-methoxy-5-(2′-ethyl-hexyloxy)-1,4-phenylene vinylene] (MEH-PPV) or small molecules such as C60 and C70 (fullerenes) or derivatives thereof, for example phenyl-C61-butyric acid methyl ester (PCBM), perylene derivatives, for example perylene tetracarboxylic derivative, bis(phenethylimido)perylene.

It will be appreciated by persons skilled in the art that materials listed as donors may function as acceptors relative to other materials, depending on their energy levels comparative to those other materials. In the same way, materials listed as acceptors may function as donors.

Preferably, the photoactive layer comprises a blend of poly (3-hexylthiophene) (P3HT) with phenyl-C61-butyric acid methyl ester (PCBM).

In some embodiments the cell may comprise a further layer. The further layer may be a metal layer, e.g. a thin Au layer, or a carbon-based layer such as carbon nanotube or graphene.

Preferably, the further layer is disposed between the hole collection layer and electrode and may serve to reduce resistance.

In some embodiments additional electron or hole transporting layers may be inserted between the electrode structures and the active layer. These may include organic or inorganic semiconductor materials.

Preferably, the photovoltaic cells are arranged in electrical series.

Preferably, the module has a power conversion efficiency (PCE) of greater than about 2.0%, more preferably between about 2.0 and 10%, even more preferably between about 2.0 and 5%, e.g. about 2.5%.

Preferably, the module has a fill factor of greater than about 30%, more preferably between about 30 to 75%, even more preferably between about 35 to 50%, e.g. about 40%.

Preferably, the module has an open circuit voltage (Voc) of greater than about 1000 mV, more preferably between about 1000 and 5000 mV, even more preferably between about 1200 and 2500 mV, e.g. about 1800 mV.

Preferably, the module has a short circuit current density (Jsc) of less than about 8 mA/cm², more preferably between about 2 and 8 mA/cm², even more preferably between about 3 and 6 mA/cm², e.g. about 4.0 mA/cm².

In alternative embodiments of the invention, other electrical configurations may be utilised. For example, the photovoltaic cells may be arranged in parallel or a combination of parallel and series interconnected cells to develop the required current and voltage output to power a particular product.

Preferably, the two or more photovoltaic cells comprise substantially equal area. For example, the area of the photoactive layer in the first cell may be identical to the area of the photoactive layer in the second cell.

Other embodiments are envisaged where the cells may comprise unequal areas. For example, the area of the photoactive layer in the first cell may be greater than the area of the photoactive layer in the second cell. This is advantageous when the current output of adjacent photovoltaic cells is not balanced. Thus, the power output may be optimised by adjusting the area of one or more cells.

In some embodiments a tandem cell structure may be adopted. In this case each cell unit of the module is formed from two cells stacked on top of each other. This structure is realised by depositing two active layers, one with a wider bandgap (located closest to the transparent contact) and the other with a smaller bandgap, tuned to absorb light of lower energy (located furthest from the transparent substrate). The two active layers are separated by a transparent or semi transparent interconnection layer or layers. In the case of the “standard” structure OPV architecture, the interconnection layer or layers form the cathode of the lower cell and anode of the upper cell. In the case of the “inverted” structure OPV architecture, the interconnection layer or layers form the anode of the lower cell and cathode of the upper cell. The tandem cell architecture allows a greater proportion of the solar spectrum to be captured and gives a higher output voltage. An example of a tandem cell structure may be found in Solar Energy Materials and Solar Cells Volume 94, Issue 2, February 2010, Pages 376-380.

A second aspect of the present invention provides a pair of photovoltaic cells, each cell comprising a pair of electrodes having an organic photoactive layer interposed therebetween, wherein at least one of the pair of electrodes is continuous across the first and second cells.

A further aspect of the present invention provides a method for manufacturing a photovoltaic module, the method comprising depositing a first electrode layer; depositing a first interfacial layer onto the first electrode layer; depositing a organic photoactive layer onto the first interfacial layer; preferably, depositing a second interfacial layer onto the photoactive layer; and depositing a second electrode layer onto the photoactive layer or, if present, the second interfacial layer, wherein the first interfacial layer comprises a hole collection moiety and an electron collection moiety.

A yet further aspect of the present invention provides a device comprising a module as described herein.

Preferably, the device is a solar panel, e.g. for the direct conversion of light to electricity.

In order that the invention may be more readily understood, it will now be described by way of example only and with reference to the accompanying drawings, in which:

FIG. 4 shows a cross section of a photovoltaic module according to the invention;

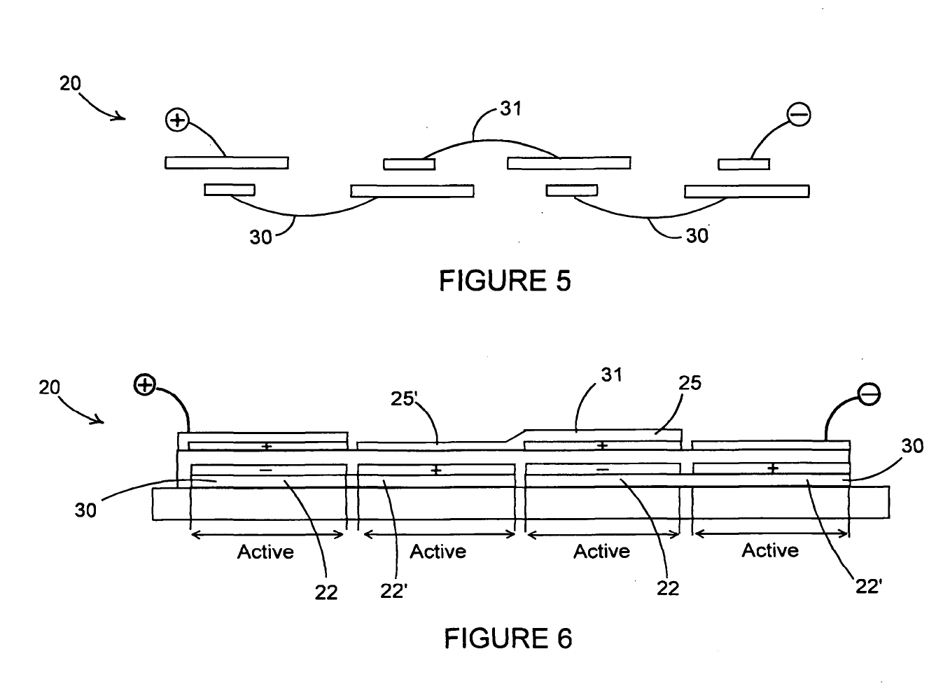

FIG. 5 shows a circuit diagram which corresponds to the photovoltaic module of FIG. 4; and

FIG. 6 shows a cross section of another photovoltaic module according to the invention.

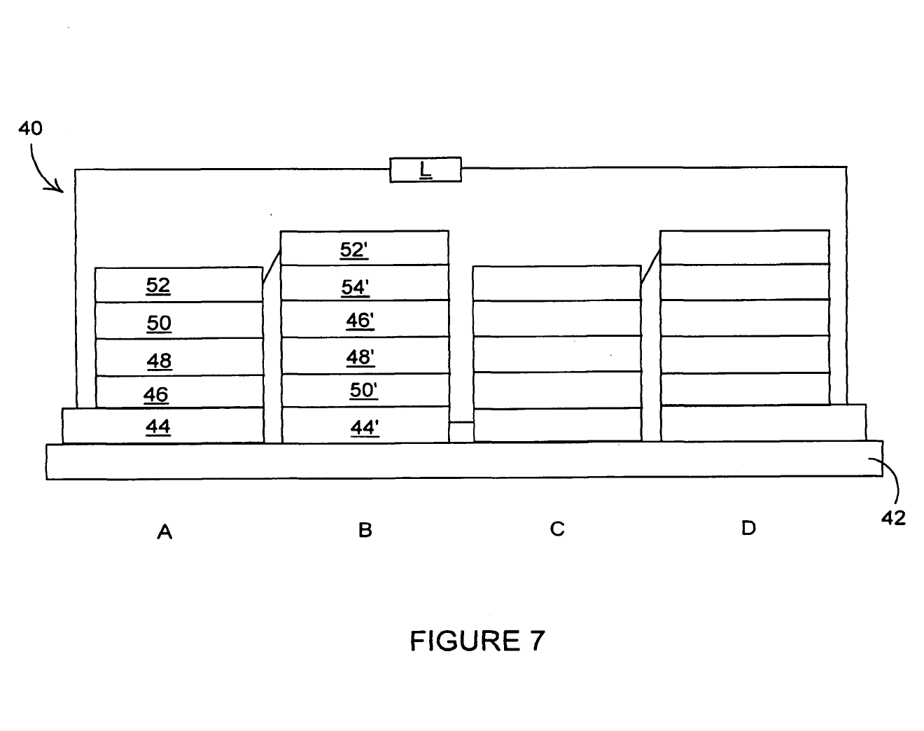

FIG. 7 shows a schematic representation of another photovoltaic module according to the invention.

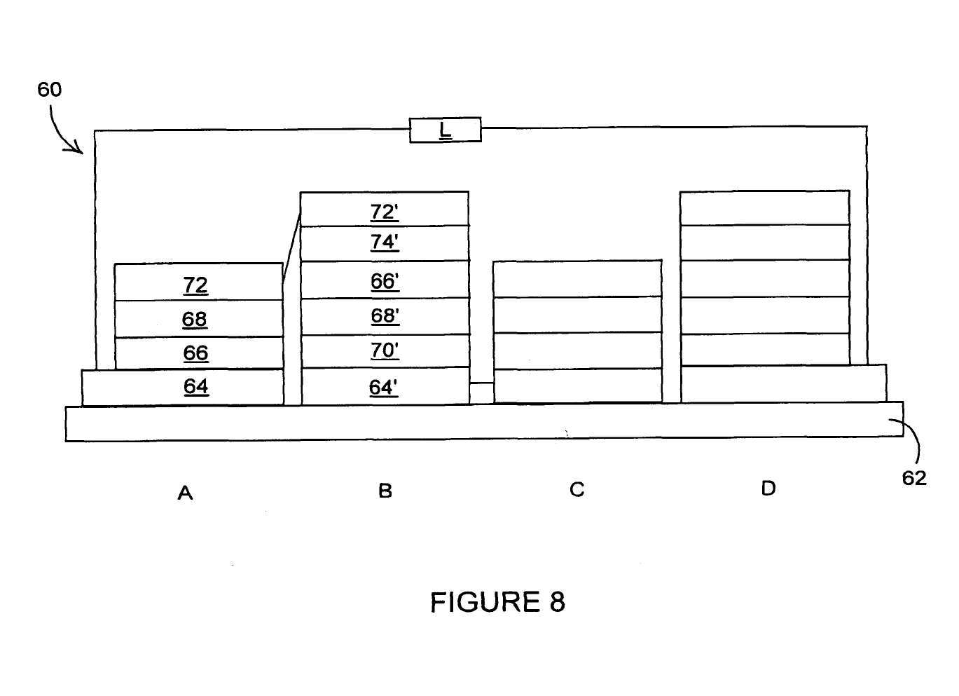

FIG. 8 shows a schematic representation of another photovoltaic module according to the invention.

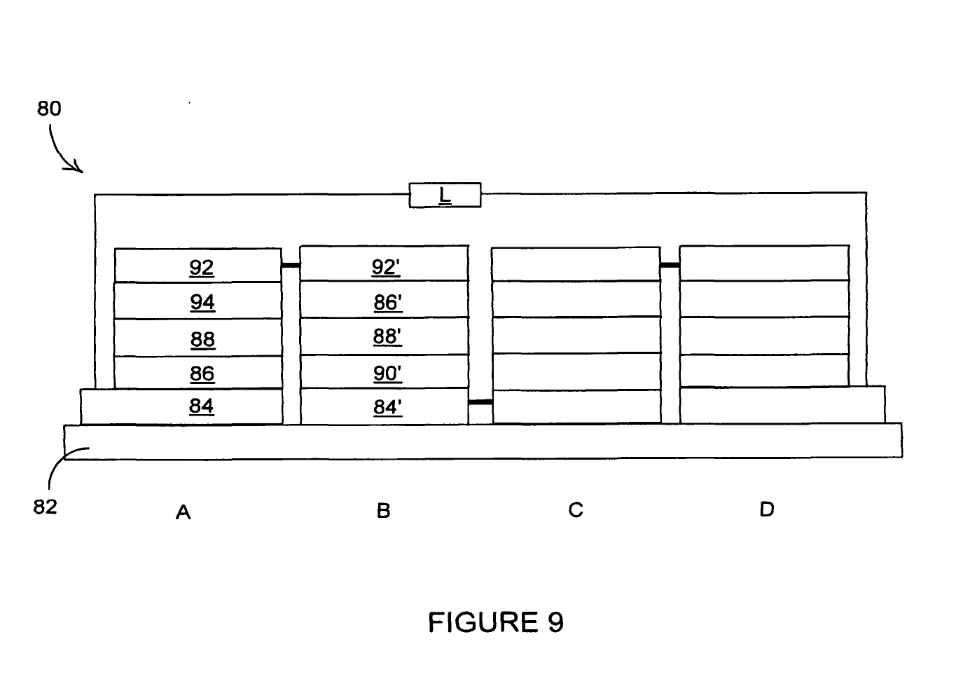

FIG. 9 shows a schematic representation of another photovoltaic module according to the invention.

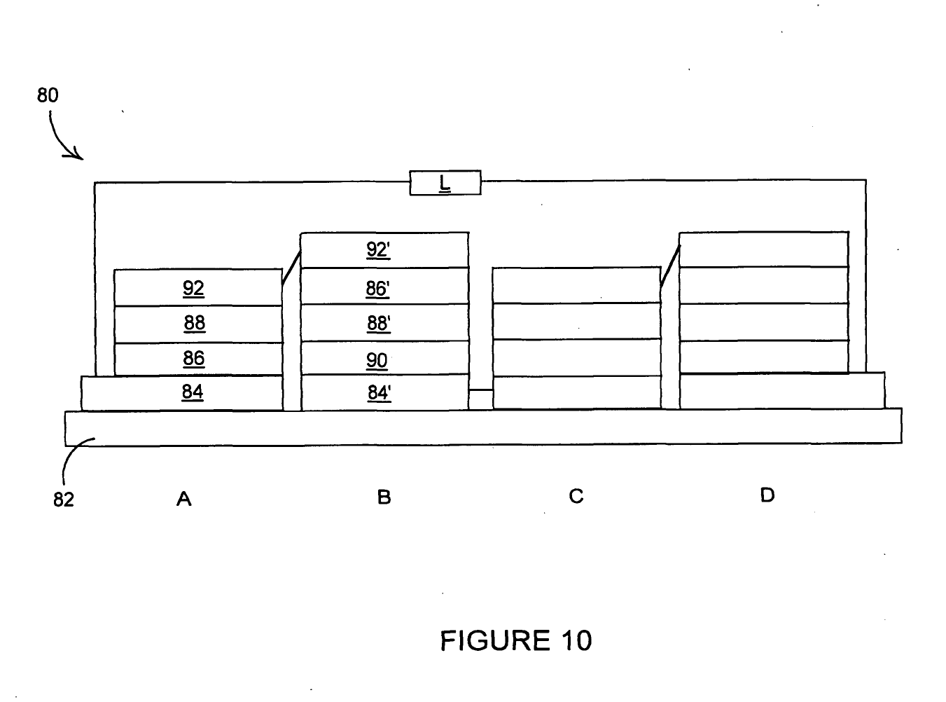

FIG. 10 shows a schematic representation of another photovoltaic module according to the invention.

Referring first to FIG. 4, there is shown a photovoltaic module 20 according to the present invention.

The module 20 comprises, in series, first A, second B, third C and fourth D photovoltaic cells, each of which having being deposited onto a common transparent glass or plastic substrate 21.

Cells A and C are identical to each other and are termed herein as “standard” ells. Likewise, cells B and D are identical to each other and are termed herein as “inverted” cells. Therefore, only standard cell A and inverted cell B will be described in detail.

Cell A comprises, from the substrate 21, a first electrode layer 22, e.g. of transparent indium tin oxide (ITO), an interface layer 23, e.g. a hole collection layer such as PEDOT:PSS, a photoactive layer 24, e.g. P3HT:PCBM and a second electrode layer 25, e.g. of aluminium.

Cell B comprises, from the substrate 21, a first electrode layer 22′, e.g. of transparent indium tin oxide (ITO), a first interface layer 23′, e.g. an electron collection layer such as TiOₓ, a photoactive layer 24′, e.g. P3HT:PCBM a second interface layer 26′, e.g. a hole collection layer and a second electrode layer 25′, e.g. of aluminium.

In the embodiment being described the ITO layer 22, 22′ serves as the anode contact for the standard cells A and C and the cathode contact for the inverted cells B and D. Similarly, the aluminium layer 25, 25′ serves as the cathode contact for the standard cells A and C and the anode contact for the inverted cells B and D. This is due to functionality imparted by the interface layer (hole collection or electron collection) attached thereto.

The cells A-D are deposited, e.g. by inkjet printing, flexographic coating, gravure coating or slot die coating etc., in a similar manner to that of known photovoltaic cells.

The hole collection layer 23, 26′ comprises PEDOT:PSS and is approximately 30 to 60 nm thick. The electron collection layer 23′ comprises a metal oxide layer such as TiOₓ (e.g. TiO₂) and is approximately 10 to 30 nm thick.

Both the hole collection layer 23, 26′ and electron collection layer 23′ are solution processable, and therefore it is to be appreciated that the layers 23, 23′, 26′ can be deposited under the same or similar treatment conditions. In this case, printing was carried out at ambient temperature.

The photoactive layer 24, 24′ is deposited, e.g. by inkjet printing, flexographic coating, gravure coating or slot die coating etc, as a single layer having an approximate thickness of 200 nm. In the embodiment being described, the photoactive layer 24 comprises P3HT: PCBM.

The aluminium layer 25, 25′, 25″ is selectively deposited across the top of the module 20 to have a thickness of approximately 100-200 nm.

As is shown in FIG. 4, there are discontinuities 100 between the electrode layer 22 and hole collection layer 23 of the first cell A and the electrode layer 22′ and electron collection layer 23′ of the second cell B. The same discontinuity 100′ exists between the corresponding layers of the third C and fourth D cells. In contrast, there is no discontinuous region between the corresponding layers of the second B and third C cells.

Further, because the photoactive layer 24, 24′ is printed across the entire module 20, the discontinuities 100, 100′ are filled with the photoactive layer 24, 24′.

A further discontinuity 101 exists between the hole collection layer 26′ and electrode layer 25′ of second cell B and the electrode layer 25″ of third cell C. In contrast, there are no discontinuous regions between the corresponding layers of the first A and second B cells or the third C and fourth D cells.

The discontinuous regions 100, 100′, 101 are formed as a consequence of patterning. The patterns may be effected by additive patterning, e.g. via a masking or printing technique, or by subtractive patterning of a blanket-deposited film, e.g. by photolithography or wet and/or dry etching.

The selective patterning enables pairs of standard cells A, C and inverted cells B, D to share single electrodes. In other words, bridges are formed between the cells A-D to connect cells in a series configuration and enable current to flow therebetween.

FIG. 5 depicts a circuit diagram which corresponds to the architecture of the module 20 of FIG. 4. In addition, FIG. 6 shows a simplified schematic diagram of the module 20 of FIG. 4.

FIGS. 5 and 6 exemplify how the current flows from one cell to another cell by way of bridges 30, 31. As will be appreciated, the electrode layer 22 of first cell A is shared by a bridge 30 with the electrode layer 22′ of second cell B. Similarly, the electrode layer 25′ of second cell B is shared by a bridge 31 with the electrode layer 25 of third cell C. The shared electrode layers in each case may serve as the anode or the cathode depending on the functionality imparted by the interface layer attached thereto.

The concept of bridging 30, 31 the electrodes in the photovoltaic module 20 is very different from interconnection between electrodes of prior art photovoltaic modules 10. For example, the sharing of a single electrode precludes the need for interconnection across the layers of a single cell, thereby increasing simplicity of manufacture. Additionally, as illustrated in FIG. 6, with certain configurations of this invention, connection to the external circuit is only made to the upper electrode layer-in contrast to the conventional OPV module structure which requires one connection to the external circuit to be made to the lower electrode layer. As a result, it is not necessary to selectively remove the active layer and other organic layers to make an external contact with the lower electrode, further reducing the patterning requirements. In addition, typically the lower electrode has a higher resistivity than the upper electrode, and so voltage drops associated with the resistivity of tracks formed by the lower electrode materials to make connections to the external circuit are eliminated.

The architecture of module 20 removes or at least significantly reduces the induction of short circuits within individual cells. This is due in part to greater robustness, i.e. avoiding areas of weakness between adjacent cells. Moreover, the architecture of module 20 demonstrates greater or at least comparable efficiency to prior art modules 10.

It is also expected that the architecture of module 20 will result in a higher production yield and lower effective cost.

Further, because pairs of standard A, C and inverted B, D cells share electrodes, it is possible to utilize a single photoactive layer 24, 24′ across the module 20. In prior art modules 10, each cell E, F, G comprises its own distinct photoactive layer 24, 24′, which is time consuming to deposit.

Thus, modules 20 provide an increased photocurrent generation area of the entire module 20 by reducing the size and/or number of interconnection spaces. As such, the aperture ratio of the module is greater than 50%, e.g. between 50-99%, e.g. 75% or 80%.

For instance, the maximum area of interconnection of the module 20 is one third of the area of interconnection of a prior art module 10. This reduction in area ensures that the aperture ratio (the ratio of active to non active area) is significantly increased.

It will be appreciated that the proposed modules 20 have an architecture which has greater versatility and flexibility over prior art modules 10. For example, it is possible to create an active area in one cell which is greater, smaller or equal in size to the active area of a neighboring or other cell.

A further OPV module 40 is shown schematically in FIG. 7. The cells A, B, C, D are arranged in series on a substrate 42. A load L is applied across the module 40. Cells A and C are identical to each other. Likewise, cells B and D are identical to each other. Therefore, only cell A and cell B will be described in detail.

The first cell A, of standard structure, comprises from the substrate 42 a first electrode layer 44, a first hole collection layer 46, a first photoactive layer 48, a first electron collection layer 50 and a second electrode 52.

The second cell B, which is of inverted structure and discrete from the first cell A, comprises from the substrate 42 a first electrode layer 44′, a first electron collection layer 50′, a first photoactive layer 48′, a first hole collection layer 46′, a second electrode 54′ and a third electrode 52′.

The second electrode 52 of the first cell and the third electrode 52′ of the second cell are of the same material (a low work function metal, e.g. Al) and form the bridging contact between the first cell A and the second cell B.

The second electrode 54′ is of a high work function metal, e.g. Au.

In the embodiment being described the first electrode layer 44′ serves as the cathode contact for inverted cell B and as the anode contact for standard cell C. Similarly, the second electrode 52 and the third electrode 52′ serves as the cathode contact for the standard cell A and the anode contact for the inverted cell B.

A further OPV module 60 is shown schematically in FIG. 8. The cells A, B, C, D are arranged in series on a substrate 42. A load L is applied across the module 60. Cells A and C are identical to each other. Likewise, cells B and D are identical to each other. Therefore, only cell A and cell B will be described in detail.

The first cell A, of standard structure, comprises from the substrate 62 a first electrode layer 64, a first hole collection layer 66, a first photoactive layer 68 and a second electrode 72.

The second cell B, which is of inverted structure and discrete from the first cell A, comprises from the substrate 62 a first electrode 64′, a first electron collection layer 70′, a photoactive layer 68′, a first hole collection layer 66′, a second electrode 74′ and a third electrode 72′.

The second electrode 72 of the first cell and the third electrode 72′ of the second cell are of the same material (a low work function metal, e.g. Al) and together form the bridging contact between the first cell A and the second cell B.

The second electrode 74′ is of a high work function metal, e.g. Au.

The hole collection layers 66, 66′ are of the same material, e.g. PEDOT:PSS.

The photoactive layers 68, 68′ are of the same material.

In the embodiment being described the first electrode layer 64′ serves as the cathode contact for inverted cell B and as the anode contact for standard cell C. Similarly, the second electrode 72 and the third electrode 72′ serves as the cathode contact for the standard cell A and the anode contact for the inverted cell B.

A further OPV module 80 is shown schematically in FIG. 9. The cells A, B, C, D are arranged in series on a substrate 82. A load L is applied across the module 80. Cells A and C are identical to each other. Likewise, cells B and D are identical to each other. Therefore, only cell A and cell B will be described in detail.

The first cell A, of standard structure, comprises from the substrate 82 a first electrode layer 84, a first hole collection layer 86, a first photoactive layer 88, a second electrode layer 94 and a third electrode layer 92.

The second cell B, of inverted structure, comprises from the substrate 82 a first electrode layer 84′, a first electron collection layer 90′, a first photoactive layer 88′, a first hole collection layer 86′ and a second electrode 92′.

The second electrode 92 of the first cell and the second electrode 92′ of the second cell are of the same material (a high work function metal, e.g. Au) and together form the bridging contact between the first cell A and the second cell B.

The second electrode 94 is of a low work function metal, e.g. Al.

The hole collection layers 86, 86′ are of the same material, e.g. PEDOT:PSS.

The photoactive layers 88, 88′ are of the same material.

In the embodiment being described the first electrode layer 84′ serves as the cathode contact for inverted cell B and as the anode contact for standard cell C. Similarly, the third electrode 92 and the second electrode 92′ serves as the cathode contact for the standard cell A and the anode contact for the inverted cell B.

FIG. 10 illustrates another OPV module according to the invention. Since many of the components illustrated in FIG. 9 are the same they are indicated by the same reference numerals. The modification from one to the other will be emphasized. The second electrode 94 of cell A is omitted.

A further OPV module will now described wherein:

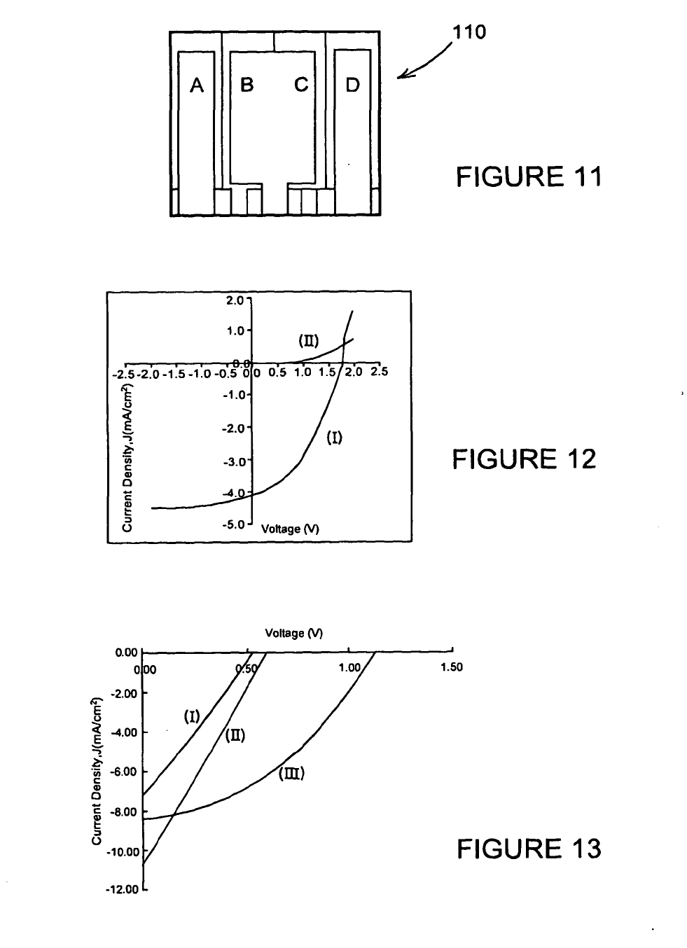

FIG. 11 shows a cross section of a photovoltaic module according to the invention;

FIG. 12 shows a current-voltage (1-V) curve of the module of FIG. 11; and

FIG. 13 shows individual current-voltage (1-V) curves of a standard cell, an inverted cell and a pair of standard and inverted cells of the module of FIG. 11.

FIG. 11 illustrates an OPV module 110 according to the present invention. The module 110 comprises, in series, first A, second B, third C and fourth D photovoltaic cells, each cell A to D having been deposited onto a common glass substrate.

Cells A and C are standard and cells B and D are inverted. Cell A comprises, from the base, an ITO electrode layer, an interface layer comprising PEDOT:PSS, a photoactive layer, an electron collection layer and a silver electrode layer. Cell B comprises, from the base, an ITO electrode layer, an electron collection layer comprising TiO₂, a photoactive layer, a hole collection layer comprising MoO₃ and a silver electrode layer. The photoactive layer comprises a blend of donor polymer and fullerene PCBM-70.

The module 110 was configured by depositing the PEDOT:PSS, TiO₂, photoactive and electron collection layers by spray coating. The MoO₃ and a silver electrode layer were deposited by thermal deposition under vacuum.

The approximate layer thicknesses are as follows: PEDOT:PSS [30 nm], TiO₂ [20 nm], photoactive layer [200 nm], electron collection layer [5 nm], MoO₃ [10 nm] and silver [200 nm]. Each cell A-D has an active area of 4 cm²; thus the total active area of the module 110 is 16 cm².

FIG. 12 shows a current-voltage (I-V) curve of the whole module 110. The I-V curve was generated under one-sun conditions, which are assumed to be 1,000 watts of solar energy per square metre. The current density under light conditions is depicted by line I and the current density under dark conditions is depicted by line II. The current density, shown on the y-axis, is expressed in milliamps per centimeter squared. The voltage, shown on the x-axis, is expressed in volts (V).

The power conversion efficiency (PCE) of module 110 was determined to be 2.88%. The open circuit voltage (Voc) and short circuit current density (Jsc) were calculated to be 1814 mV and 4.069 mA/cm², respectively. The module 110 fill factor (FF) was 39.1%.

Due to the alternating nature of the cells A to D it was possible to sample data characterizing the individual cells (i.e. standard or inverted) alone and the half module (comprising one standard and one inverted cell) for comparative purposes. FIG. 13 shows the I-V curves under one-sun light conditions of a single standard cell A (line I), a single inverted cell B (line II) and a half module comprising cells A and B (line III).

Data for the individual cells and the half module are shown in Table 1.

TABLE 1
Device data for individual cells (inverted and standard) and half module.

| | Active | | | | | |
|---|---|---|---|---|---|---|
| | Area | Jsc | Voc | Fill Factor | PCE | Rseries |
| Sample | (cm²) | (mA/cm²) | (mV) | (%) | (%) | (Ω · cm²) |
| Inverted cell | 4 | 11.271 | 599 | 26.61 | 1.79 | 54.9 |
| Standard cell | 4 | 7.679 | 547 | 25.70 | 1.08 | 54.8 |
| Half module | 8 | 8.293 | 1134 | 40.60 | 3.81 | 32.8 |

An OPV device produces maximum current when there is no resistance in the circuit, i.e. when there is a short circuit between the positive and negative terminals applied to the device. In other words, when the device is shorted, the voltage in the circuit is zero since there is no resistance. The maximum current density is known as the short circuit current density, Jsc. Conversely, a maximum voltage occurs when there is a break in the circuit known as the open circuit voltage, Voc. Under this latter condition the resistance is infinitely high and there is no current since the circuit is not complete. The power available from a device is the product of the current density and voltage at any point along the I-V curve. Thus, the power available from module 110 under light conditions is the product of the current density and voltage at any point along line I of FIG. 12.

With reference to Table 1 above, the open circuit voltage (Voc) of the half module is 1134 mV, i.e. approximately twice that of the individual inverted B or standard A cells (which have Voc of 599 mV and 547 mV, respectively). This is as expected because the individual cells are connected in series. The short circuit current density (Jsc) of the half module is 8.293 mA/cm², i.e. approximately equal to that of the cell with the lower electrical current, namely standard cell A which has a Jsc of 7.679 mA/cm². The series resistance (Rseries) of the half module is 32.8 Ω·cm², which is significantly lower than the series resistance of either inverted B (54.9 Ω·cm²) or standard A (54.8 Ω·cm²) cells alone. Thus, as a consequence, the power conversion efficiency (PCE) of the half module is 3.81%, i.e. more than three times greater than the less efficient cell, namely standard cell A which has a PCE of 1.08%. In other words, the power conversion efficiency (PCE) is not dominated by the less efficient cell. Rather, the efficiency is improved due to the novel architecture of the device. The use of a highly conductive electrode layer such as silver further improves the device performance since this reduces series resistance and consequently increases the device PCE.

Since cells A to B of the module 110 as shown in FIG. 11 alternate in series there is no requirement for there to be a tunneling connection between the first electrode layer of cell A and the electrode layer of opposite polarity of cell B, as would be the case in the prior art (e.g. as shown in the module of FIG. 1). Thus, the aperture ratio (i.e. active area) of the module 110 is greater than the aperture ratio (active area) of the prior art module. This novel architecture leads to a reduction in component dead space and/or lower resistance across the device and/or a higher fill factor and/or greater power conversion efficiency and/or simplified manufacture of the module 110.

Of course, the embodiments described herein are merely examples of the present invention. It is to be appreciated that the layers (electrode, hole collection, electron collection or photoactive) of a given module 20 may comprise the same or different materials depending on the proposed use for the module 20. Additionally, some layers may be omitted and additional layers may be added, for example, one or both of the “inverted” or “standard” structures may be absent an electron or hole collecting layer, the type of structure being defined by the direction of flow of electrons through the cell. Further, a layer or layers may be cured, dried, annealed or otherwise treated after deposition and/or patterning, as appropriate.

As will be apparent to those skilled in the art in light of the foregoing disclosure, many alterations and modifications are possible in the practice of the invention without departing from the spirit of scope thereof. Accordingly, the scope of the invention is to be construed in accordance with the substance defined in the following claims.

1. A photovoltaic module comprising a substrate having at least a first and a second photovoltaic cell mounted thereon, the two cells being adjacent and connected, in series, and wherein, in use, current flow through a photoactive layer of the first photovoltaic cell is in a different, substantially opposite, direction, relative to the substrate, to that through a photoactive layer of the second photovoltaic cell.

2. A photovoltaic module comprising a photovoltaic cell of standard structure connected in series with a photovoltaic cell of inverted structure.

3. A module according claim 1, wherein at least one or both photovoltaic cells are organic photovoltaic cells.

4. A module according to claim 1, wherein the or a photoactive layer is shared between the at least two cells.

5. A module according to a claim 1, wherein the or a photoactive layer of at least one cell is discrete.

6. A photovoltaic module having two or more photovoltaic cells, each cell comprising a pair of electrodes having an organic photoactive layer interposed therebetween, wherein the photoactive layer is shared between the at least two cells.

7. A module according to claim 6, wherein at least two of the photovoltaic cells are adjacent to one another and of alternate standard and inverted structure.

8. A module according to claim 1, wherein the or a photoactive layer is a non-patterned layer.

9. A module according to claim 1, wherein the module comprises a plurality, e.g. four or more, of organic photovoltaic cells.

10. A module according to claim 1, wherein the or a photoactive layer of the first cell comprises the same composition as the or a photoactive layer of the second cell.

11. A module according to claim 1, wherein the photoactive layer of the first cell comprises a different composition as the photoactive layer of the second cell.

12. A module according to claim 1, wherein the two or more photovoltaic cells comprise substantially equal area.

13. A module according to claim 1, wherein the cells comprise unequal areas.

14. A module according to claim 1, wherein the photoactive layer comprises a binary system of a donor moiety and an acceptor moiety.

15. A module according to claim 14, wherein at least one of the donor moiety or acceptor moiety comprises an organic semiconductor.

16. A module according to claim 14, wherein at least one of the donor moiety or acceptor moiety comprises an inorganic semiconductor.

17. A module according to claim 6, wherein at least one of the pair of electrodes is a transparent conducting oxide (TCO).

18. A module according to claim 1, wherein at least one of the two or more cells comprises a hole collection layer and/or an electron collection layer.

19. A module according to claim 18, wherein the hole collection layer comprises a conductive polymer such as poly(3,4-ethylenedioxythiophene) poly(styrenesulfonate) (PEDOT:PSS).

20. A module according to claim 18, wherein the electron collection layer comprises a metal oxide.

21. A module according to claim 20, wherein the metal oxide is deposited using sol-gel coating, deposition of a nanoparticle dispersion, thermal deposition in the vacuum or spray pyrolysis.

22. A module according to claim 18, wherein the hole collection layer is approximately 10 to 100 nm thick, more preferably, 20 to 100 nm thick, even more preferably 30 to 60 nm thick, e.g. 40 nm thick.

23. A module according to claim 18, wherein the electron collection layer is approximately 5 to 60 nm thick, more preferably 10 to 40 nm thick, even more preferably 10 to 30 nm thick, e.g. 20 nm thick.

24. A module according to claim 1, wherein the photoactive layer is approximately 5 to 1000 nm thick, more preferably 50 to 500 nm thick, even more preferably 100 to 300 nm thick, e.g. 200 nm thick.

25. A module according to claim 1, wherein the photoactive layer is approximately 10 to 200 nm thick, e.g. 70 to 100 nm thick.

26. A module according to claim 1, wherein the electrode layer is approximately 20 to 500 nm thick, more preferably 40 to 250 nm thick, even more preferably 60 to 150 nm thick, e.g. 100 nm thick.

27. A module according to claim 1, wherein the photoactive layer comprises a blend of poly(3-hexylthiophene) (P3HT) with phenyl-C61-butyric acid methyl ester (PCBM).

28. A module according to claim 1 further comprising an additional layer such as a metal layer, e.g. a thin Au layer, or a carbon-based layer such as carbon nanotube or graphene.

29. A module according to claim 1 having a power conversion efficiency (PCE) of greater than about 2.5%.

30. A combination of first and second photovoltaic cells located adjacent one another, the first and the second cells each comprising upper and lower electrodes having an organic photoactive layer interposed therebetween, wherein the upper electrode of the first cell is connected to, e.g. shared with, the upper electrode of the second cell or the lower electrode of the first cell is connected to, e.g. shared with, the lower electrode of the second cell.

31. A method for manufacturing a photovoltaic module comprising at least two photovoltaic cells, the method comprising depositing a continuous organic photoactive layer so as to be shared by adjacent cells.

32. A device comprising a module according to claim 1.

33. A device according to claim 32, wherein the device is a solar panel.

34. (canceled)

35. (canceled)

36. (canceled)

37. (canceled)
